(19) United States
(12) Patent Application Publication
(10) Pub. No.: US 2013/0180587 A1
(43) Pub. Date: Jul. 18, 2013

(54) Solar Cells

(71) Applicants: John C. Warner, Wilmington, MA (US); Michael S. Viola, Burlington, MA (US); Olga Barykina, Boston, MA (US); Vineet Dua, Parma Heights, OH (US)

(72) Inventors: John C. Warner, Wilmington, MA (US); Michael S. Viola, Burlington, MA (US); Olga Barykina, Boston, MA (US); Vineet Dua, Parma Heights, OH (US)

(21) Appl. No.: 13/351,626

(22) Filed: Jan. 17, 2012

(51) Int. Cl. H01L 31/0216; H01L 31/18

(52) U.S. Cl. 136/257; 438/70; 257/E31.121

(57) ABSTRACT

Disclosed and claimed herein are methods of preparing colorant sensitized solar cells using pre-sensitized semiconductor particles, said particles are coated and thermally processed at temperatures that maintains the sensitivity of the colorant. The pre-sensitized particles are prepared in an aqueous or organic solvent colorant admixture. The solar cells may contain heat sensitive substrates as well as heat resistant substrates. Also disclosed and claimed are solar cells prepared from the disclosed and claimed pre-sensitized semiconductor particles as well as the colorant/particle dispersion.

### FIELD OF INVENTION

The present disclosure is in the field of solar cells, more particularly in the field of solar cells which contain a colorant sensitized semiconductor layer prepared from a presensitized semiconductor composition which was processed at low temperature.

### BACKGROUND

Solar cells convert energy received from the sun into usable electricity and are considered an environmentally friendly energy source when compared to fossil fuel energy sources. Examples of solar cells include silicon-based solar cells and dye sensitized solar cells (DSSC). In the case of silicon-based solar cells, manufacturing costs are high, materials used to make are costly and little can be done to improve their efficiency. DSSCs are a low cost, effective alternative to silicon-based solar cells and are becoming the solar cell of choice in many applications. Not only are the materials used to make them lower cost and the manufacturing costs are low, they are flexible and more robust than the silicon-based solar cells.

Typically DSSC are prepared from titanium dioxide (TiO₂), used as the semiconductor. Since TiO₂ only absorbs a fraction of the solar spectrum that is received from the sun, sensitizing dyes are used to capture a larger portion of the solar spectrum and thus become more efficient. Not to be held to theory, it is believed that a photon excites the sensitizing dyes into an excited state from which an electron is injected into the TiO₂ matrix and which is then transported to an external conductor which then carries the electron to an electromotive device or a battery.

DSSC are typically manufactured by coating a substrate containing an electrode, typically indium tin oxide, with a dispersion of TiO₂ particles. The resulting coating is then heat treated at 460° C. for 45 minutes in order to make it nanoporous as well as to sinter the TiO₂. The resulting coated material is then immersed in a dye dispersion in

Despite the fact that DSSCs use less expensive materials than silicon-based solar cells and the manufacturing process is cheaper and less complicated, the process uses high temperatures for sintering thus restricting the types of substrates and materials that can be used. Also DSSCs require organic solvents for dyeing the semiconductor after the sintering process. Thus there remains a need to provide a more environmentally friendly process, using less energy and less environmentally unfriendly materials to make the next generation of DSSCs. There also remains a need to further reduce the costs of manufacturing solar cells.

### BRIEF DESCRIPTION OF THE DRAWINGS

FIG. 1 shows a side view of a substrate containing a conductor with sensitizing colorant associated with a semiconductor.

FIG. 2 show a side view of a colorant sensitized solar cell.

### SUMMARY OF THE INVENTION

The present disclosure provides for the preparation of DSSCs using low cost, environmentally friendly process steps including steps which reduce the reliance on high temperature processing and the use of water based colorant compositions. The present disclosure also provides for the DSSCs made by the environmentally friendly process steps.

In a first embodiment, the present application for patent discloses and claims a method for forming a solar cell comprising the steps of, providing a substrate comprising a conductor; applying a composition containing a sensitizing colorant and semiconductor particles and processing the composition. The composition contains a sensitizing colorant, semiconductor particles and water, and can be processed below the decomposition temperature of the colorant which can range from about 250° C. to about 500° C. The colorant can be chosen to absorb at specific wavelengths of the solar spectrum.

In a second embodiment, the present application for patent discloses and claims a method for forming a solar cell comprising the steps of, providing a substrate comprising a conductor; applying a composition containing a plurality of sensitizing colorants and/or a plurality of semiconductor particles and processing the composition. The composition contains a plurality of sensitizing colorants, a plurality of semiconductor particles and water, and can be processed below the decomposition temperature of the colorant which can range from about 250° C. to about 500° C. The colorants can be chosen to absorb at a plurality of wavelengths of the solar spectrum.

In a third embodiment, the present application for patent discloses and claims a solar cell comprising a substrate containing a conductor and a processed layer formed from a composition containing a sensitizing colorant, a semiconductor particles and water, wherein the processed layer is processed at a temperature below the decomposition temperature of the colorant which can range from about 250° C. to about 500° C.

In a fourth embodiment, the present application for patent discloses and claims a solar cell comprising a substrate containing a conductor and a processed layer formed from a composition containing a plurality of sensitizing colorants, and/or a plurality of semiconductor particles and water, wherein the processed layer is processed at a

In a fifth embodiment, the present application for patent discloses and claims a method for forming a colorant-sensitized semiconductor particle composition solar cells comprising the steps of forming an admixture of a sensitizing colorant in water and admixing semiconductor particles.

In a sixth embodiment, the present application for patent discloses and claims a method for forming a colorant-sensitized semiconductor particle composition solar cells comprising the steps of forming an admixture of a plurality of sensitizing colorants in water and admixing a plurality of semiconductor particles

### DETAILED DESCRIPTION OF THE INVENTION

As used herein, the conjunction “or” is not intended to be exclusive unless otherwise noted. For example, the phrase “or alternatively” is intended to be exclusive. Further, when used in connection with chemical substitution at a specific position, the conjunction “or” is intended to be exclusive

As used herein the term “conductor” refers to a material that conducts electricity and can be in the form of a layer, a matrix of lines, or other configurations.

As used herein the term “plurality” means more than one.

As used herein the term “colorant” refers to any material that absorbs solar energy including, for example, dyes, pigments, photoluminescent materials, infra-red absorbers, and the like.

As used herein the term “semiconductor particle” refers to a material which has semiconductive properties as a “particle or obtains semiconductive properties when applied to a substrate and processed.

As used herein the term “dry” and dried” refer to a composition with <about 8% residual water solvent.

As used herein the term “dispersion” is meant to encompass solution, partial solution and non-solution of materials and not limiting.

As used herein the term “nanoparticle” refers to particles whose average diameter ranges from 1 to 100 nanometers.

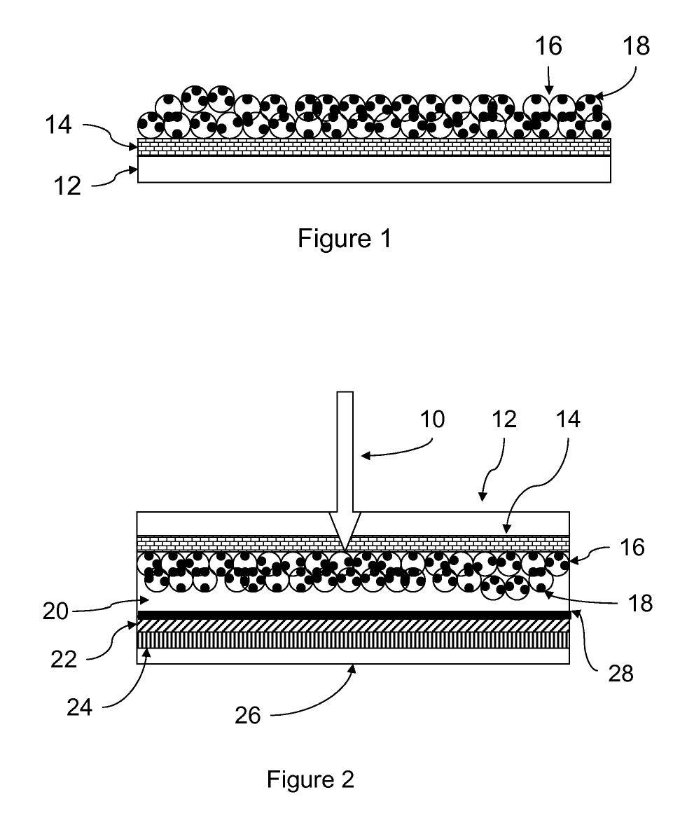

The present application for patent discloses and claims a method for forming a solar cell. Referring to FIG. 1, a substrate 12 containing a conductor 14 is provided. The substrate 12 can be heat resistant such as a glass such as silicate glass, or a heat sensitive substrate such as plastic such as, for example, polyethylene terephthalate, polyethylene naphthalate, polycarbonate, polypropylene, polyimide, triacetyl cellulose, polystyrene, and the like. The more useful materials will have the higher transparency to the wavelengths of interest in the solar cell, but lower transparency will also function. The conductor 14 may fully or partially cover the substrate. The conductor may be a conductor that has transparency to solar energy such as, for example, indium tin oxide, fluorine-doped tin oxide, zinc oxide-gallium oxide, zinc oxide-aluminum oxide, antimony-doped tin oxide, tin-doped indium oxide, or the like, and combinations thereof. The conductor may also be made from a number of conductive materials that are not transparent to solar radiation such as, for example, silver, gold, copper, or the like. In this case conductive lines are fabricated onto the substrate which allows solar radiation to pass through the substrate where there is no conductor. Generally, a material used as the conductor in a photovoltaic cell has at least partial transparency to the wavelength spectrum of interest in the photovoltaic cell. Many materials, such as, for example, silver can be coated thin enough to provide good transparency while still maintaining good conductivity. The desired amount of solar energy needed predicates the amount and types of conductive lines that need to be fabricated. The transparent conductive layer may also be fabricated from metal ‘nanowires’ such as silver, copper, gold and the like. In these cases the conductive pathway is formed from the overlapping and entangling of these nanowires without the creation of significant shadowing of light.

Organic transparent conductors, more commonly referred to as conductive polymers, such as, for example, polythiophenes such as, for example, PEDOT (polyethylene dioxythiophene), polypyrrole, polyaniline, polydiacetylene and the like, may also be used to fabricate transparent conductor layers. These materials may be selectively doped or undoped.

A composition comprising sensitizer colorant, semiconductor particles and water is disposed onto the substrate-conductor layers and processed to provide a layer of semiconductor 16 in FIG. 1, which is in contact with sensitizing colorant 18 in FIG. 1. Examples of semiconductor particle types include titanium oxide, strontium oxide, indium oxide, zinc oxide, zirconium oxide, cerium oxide, copper aluminate, strontium copper oxide, lanthanum oxide, vanadium oxide, molybdenum oxide, tungsten oxide, niobium oxide, magnesium oxide, aluminum oxide, yttrium oxide, scandium oxide, samarium oxide, gallium oxide, strontium titanium oxide, or a complex oxide containing a combination of these oxides. The semiconductor particles useful for the current disclosure include particles that function as semiconductors in their particle form as well as particles that do not have semiconductor properties in their particle form but are semiconductive when applied to a substrate and processed, as well as combinations thereof.

When these materials are admixed in water they are semiconductor particles; when they are disposed onto a substrate and processed, they form a semiconductive layer. The composition may comprise an admixture of semiconductor particles, such as microparticles ranging from 0.1-2.0 microns and semiconductor nanoparticles ranging from 1-100 nanometers. The ratio of particles to nanoparticles may range from 99 to 0.01.

Sensitizing colorants are any materials which can absorb a portion of the solar radiation and inject an electron into the semiconductor layer. These include dyes, pigments, photoluminescent materials, IR dyes, UV dyes, quantum dots, carbon black based materials, carbon nanotubes and the like. Dyes, for example, contain at least one acid group, such as, for example, carboxylic acids, sulfonic acids, phosphonic acids, phenol groups and α,α′-methylene dicarbonyl groups or combinations thereof, which allow the dye to associate with the semiconductor particle in a dispersion, or after disposition and processing, or both. An example of a colorant suitable for the current disclosure is (Z)-3-(4-(4-(bis(4-tert-butylphenyl)amino)styryl)-2,5-dimethoxyphenyl)-2-cyanoacrylic acid, (BASCA):

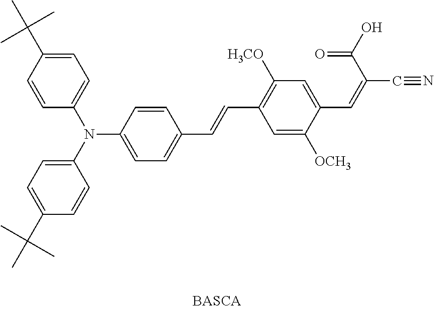 [SMILES: COc1cc(/C=C/c2ccc(N(c3ccc(C(C)(C)C)cc3)c3ccc(C(C)(C)C)cc3)cc2)c(OC)cc1/C=C(/C#N)C(=O)O]

The composition is an admixture of the semiconductor particle and sensitizing colorant in water. The slurry of particles has sizes ranging from about 0.01 to about 2 microns, while the colorant may be soluble, partially soluble or insoluble. Other materials may be added to the composition to impart certain desirable properties, such as for example, wetting agents for helping the colorant deposit onto the particle surface and/or to allow the composition to wet out the substrate/conductor surfaces during disposition. The composition may contain pH adjusting materials such as bases, such as, for example, ammonia or amines, or acids, such as nitric or acetic or other carboxylic acid containing materials, or buffers. Antifoams, defoamers, rheology agents, leveling agents, and other additives typical of coating compositions and the like may also be added. Not to be held to theory, it is believed that the colorant coordinates with the semiconductor particles resulting in pre-sensitized semiconductor particles. The colorant may further dispose onto the semiconductor particle during processing, or when in contact with the electrolyte, or any combination thereof.

The composition is disposed onto the substrate/conductor surface by any coating or printing method known in the art, for example, curtain coating, roller coating, slot coating, wire rod coating, spray coating or offset coating or the following printing processes such as lithography, screen, inkjet or gravure.

After the composition is deposited onto the substrate/conductor it is processed at a temperature below the decomposition of the colorant. In the case of dyes, the processing temperature ranges from about 250° C. to about 350° C. depending on the dye. Pigments can withstand higher temperature drying. For example, phthalocyanine BN can withstand dry to below about 600° C. before decomposing. Decomposition temperatures of the colorants may be altered when in contact with the semiconductor. The dried composition is now coated with an electrolyte composition. The electrolyte may be coated from solution, colloid or as a gel. The semiconductor particle now has obtained semiconductor properties. Drying may occur in a convection oven, IR ovens, hot plate drying, vacuum ovens and the like.

More than one colorant may be admixed in the composition in order to capture a broader spectrum of solar energy for conversion into electrons. In this manner the solar cell can be made more efficient and hence provide a lower cost per watt of energy generated. More than one semiconductor particle type may be admixed in the composition. These may be chosen, for example, to improve attraction of the colorants, or have desirable semiconductor properties, or they may be synergistic with other semiconductors, or combinations thereof. Sizes of the semiconductor microparticles may vary from about 0.1 micron to about 2 microns. Semiconductor nanoparticles ranging from 1-100 nanometers may also be mixed with the microparticle. The ratio of microparticles to nanoparticles may range from 99 to 0.01. It may be desirable to choose 2 or more ranges of sizes to allow for improved stacking of the particles and improved conductivity. For example, smaller particles may fit into the interstices of an agglomerate of larger particle thus increasing the density of the semiconductor material as well as the amount of sensitizing colorant per unit volume, again potentially increasing the efficiency of the solar cell fabricated therefrom. The temperature of drying may need to be adjusted so that the colorant with the lowest temperature of decomposition retains its sensitizing properties.

The concentrations of the colorant and semiconductor particle may be chosen to provide an optimum ratio between absorbance of solar energy and electron production. For example, when disposed onto the substrate/conductor and processed the interface between the individual semiconductor particles provides for transport of the electrons created when the colorant absorbs solar energy. If the interfaces are separated by, for example, colorant molecules electrons may not be able to be transported.

Turning now to FIG. 2 a cross section of a solar cell is shown. A substrate 12 containing a conductor 14 is provided. The sensitizing colorant 18 associated with semiconductor layer 16 of the current disclosure forms a layer on the conductor. A redox electrolyte 20 forms a layer on the semiconductor layer 16. The redox electrolyte 20, may be a gel that contains a redox couple such as I₃⁻/I⁻, Co⁺⁺⁺/Co⁺⁺, Fe⁺⁺⁺/Fe⁺⁺, Cu⁺⁺/Cu⁺, Ag⁺/Ag, tetrazoles/disulphides or ferrocinium/ferrocene in liquid, gel or solid solution form.

A second conductor 24 forms a layer which may be separated from the electrolyte layer 20 by a conductive innerlayer 22 comprised to protect the second conductor 24 from the electrolyte 20 if the electrolyte 20 is capable of corroding the second conductor 24. Contained within the conductive innerlayer 22, a catalyst may be present to enhance the red-ox reaction of the electrolyte 20 necessary to transport the electrons back to the dye. Alternatively a separate layer 28 may be formed in contact with layer 22 which acts as the catalysts. Conductive materials which are inert to the electrolyte are used as the catalyst, such as, for example, gold, platinum, palladium and other noble metals as well as graphene, carbon nanotubes and the like. Conductive polymers may also serve as catalyst components, such as, for example doped or undoped poly-ethylenedioxythiophenes, polypyrroles, polyacetylenes and polyanilines.

The second conductor layer 24 may be composed of the same material as conductor 14 and may be patterned the same or different, or it may contain other conductive materials such as, for example, platinum, palladium, silver, copper and the like. A second substrate 26, is also present and may be the same or different than substrate 12. The electrolyte 20, the second conductive layer 24, if present, the second conductor 22 and the second support 26 do not need to be transparent to light since the light 10 used by the photovoltaic cell passes through layers 12 and 14 and is captured by the photoreactive layer.

In operation, for the exemplary photovoltaic cell, light 10 passes through substrate 12, conductor layer 14, into the sensitizing colorant—semiconductor layer 16, where it can excite electrons that then are collected by the conductor 14. After flowing through the external circuit, they are re-introduced into the photovoltaic cell through the second conductor layer 24 flowing into the electrolyte 20. The electrolyte 20 then transports the electrons back to the semiconductor layer 16.

Since the semiconductor layer 16 is generally porous and since it is situated adjacent to the electrolyte 20, it can allow the electrolyte 20 to seep through and corrode the conductor. Thus a conductive innerlayer comprising an anti-corrosion conductive polymer may be present between the semiconductor layer 16 and the electrolyte 20.

The current disclosure also discloses and claims colorant sensitized solar cells prepared by the methods disclosed above.

The pH of the dying composition may be acidic in which case the dyes may aggregate and form colloidal solutions, dispersions or emulsions, which can attach, or otherwise associate themselves, with the semiconductor particles. The pH may be basic in which case the dye may form a solution from which they attach, or otherwise associate themselves with the semiconductor particles. After being deposited and processed, the pre-sensitized semiconductor layer, either deposited from a low pH or a high pH composition, may be treated with a solvent dip. Not to be held to theory it is believed that the solvent dip aids in leveling any aggregates and/or removes excess dye that may interfere with the light adsorption by the dye and the subsequent transfer of the photoelectron to the semiconductor. Suitable solvents include water, acidic water, basic water or organic solvents.

Because the method of the current disclosure uses low temperature processing to obtain the dye sensitized semiconductor, the solar cells made therefrom are not limited to high temperature substrates such as glass. Thus, substrates that are not suitable for high temperature processing can now be used. For example, plastic films coated with conductive materials such as ITO or conductive polymers or conductive metal fine grids, can be used as substrates onto which the pre-sensitized semiconductors may be coated, processed and fabricated into a solar cell. Suitable films include polyethylene terephthalate, polycarbonate, polystyrene, polypropylene and other polyolefins, polysulfones and other films. Useful films need to have some transparency to the desired wavelength used in the desired photovoltaic effect. These films are flexible so that solar cells made from them are no longer restricted to flat, rigid surfaces. Thus, the solar cells made from these flexible films can be formed into rolls, folded, waved, formed into saddles, and the like and can be formed in ways to create more efficient absorption of solar radiation. They can be used in rough environments which would cause a rigid based solar cell to break and thus fail. They can be carried on ones person in rolled or folded form.

The use of flexible plastic films allows for simpler manufacturing techniques since they can be manufactured in a roll-to-roll process. As a result, in line-processing allows for high speed, continuous manufacturing, thereby significantly lowering the costs of making the solar cells. Lower costs allow for easier and broader penetration into the market place.

### EXAMPLES

Materials used in the examples were obtained from Aldrich Chemical Co. unless otherwise indicated. Percentages are wt/wt unless otherwise indicated.

### Example 1

### Preparation of the Presensitized Semiconductor

To 1.40 g of water was added 0.75 g of a 2% Triton-X-100® solution and 0.30 g of a 5M NH₃ solution. To this was added 15 mg (24.4 micromole) of (Z)-3-(4-(4-(bis(4-tert-butylphenyl)amino)styryl)-2,5-dimethoxyphenyl)-2-cyanoacrylic acid, (BASCA) and the admixture was probe sonicated for 5 minutes (17% duty cycle) at room temperature. 0.30 g of P-25 Titania from Evonik Degussa and 0.01 g of P-200 Titania from Evonik Degussa was then added and the admixture was probe sonicated for 5 minutes (17% duty cycle) at room temperature.

### Coating of the Substrate

The presensitized semiconductor prepared in the previous step was coated onto a fluorine-doped tin oxide (FTO, 8-10 ohms/sq) treated glass substrate using a glass rod drawdown method with 50 micron tape thickness rails and processed in a convection oven at 100° C. for 15 minutes to give a first substrate. The coating coverage is targeted for about 8 to about 12 microns when dried.

### Preparation of the Solar Cell

Another piece of 2 in×2 in FTO treated glass was washed with ethanol and was then ‘painted’ with Platisol® (obtained from Solaronix, Switzerland), dried at room temperature and then baked at 450° C. for 30 minutes. 2 small holes (˜2 mm) were drilled into this piece of glass on the opposite side of the semiconductor and this piece of glass was then heat laminated to the first substrate using a piece of adhesive film (Meltonix®, obtained from Solaronix, Switzerland) cut into the shape of a rectangle and used as a ‘well’ to hold the electrolyte. Lamination was done using clamps and holding the pieces of glass together for 30 minutes @ 150° C.

After assembly the cell was filled with electrolyte (Iodolyte®, obtained from Solarorinx) through one of the filling holes drilled earlier. Both holes were then sealed with the thermal adhesive film.

The resulting cell was placed in a solar simulator and illuminated with 1 Kw/m² intensity and the efficiency of the thus obtained solar cell was determined.

The efficiency of the solar cell prepared from Example 1 was 0.75%

### Examples 2-5

Examples 2 through 5 were performed as in Example 1 except the percent of BASCA to titania in the admix was incrementally increased as shown in Table 1. The final percent solids of the examples were between 15% and 17%.

TABLE 1

| | Amount | | | Amount | |
|---|---|---|---|---|---|
| Example | of | Amount | Amount of | of | |
| % colorant: | BACSA, | of | 2 wt % | 5M | |
| semiconductor | mg | water, g | TX-100, g | NH₃, g | P25/P400, g |
| 1 (5%) | 15 | 1.40 | 0.75 | 0.30 | 0.30/0.01 |
| 2 (10%) | 30 | 1.40 | 1.50 | 0.60 | 0.30/0.01 |
| 3 (20%) | 60 | 1.40 | 3.00 | 1.20 | 0.30/0.01 |
| 4 (30%) | 90 | 1.40 | 4.50 | 1.80 | 0.30/0.01 |
| 5 (35%) | 105 | 1.40 | 5.25 | 2.10 | 0.30/0.01 |

Table 2 shows the efficiency of the solar cells prepared from the examples. Note the highest efficiency was obtained when the percent of BASCA to titania was at or around 20%.

TABLE 2

| Experiment (% BACSA to Titania) | Solar Cell efficiency (%) |
|---|---|
| 1 (5%) | 0.75 |
| 2 (10%) | 1.50 |
| 3 (20%) | 1.75 |
| 4 (30%) | 1.35 |
| 5 (35%) | 1.10 |

### Example 6

### Addition of Nanotitania to the Formulation

### Preparation of Nanotitania:

To a 2 L round-bottom flask was added approximately 1500 mL of DI H₂O and 56.2 mL of 2 N HNO₃. While stirring, 250 mL of titanium isopropoxide was added dropwise using an addition funnel. The admixture was then heated at 85° C. while stirred for 12 hrs. The resultant suspension was concentrated (using a rotary evaporator) to approx. 500 g (±5 g) in a 1 L round bottom flask and transferred into 4 pressure tubes; two 350 mL tubes and two 100 mL tubes. These pressure tubes were sealed and autoclaved at 200° C. overnight.

The autoclave oven was allowed to cool down to room temperature slowly; the pressure tubes were opened slowly to release excess pressure. The resultant nano-titania suspension was bath sonicated for 10-12 hours. The % solids were 13.79%

Preparation of Pre-Dyed Semiconductor with Nanotitania:

The nanotitania prepared in the previous step was bath sonicated for 20-30 mins. 1.4 mL of DI H₂O, 50 mg of DCA (deoxycholic acid), 0.62 g of P25 Titania, and 1.48 mL of the sonicated nanotitania were placed into 3 mL vial. This mixture was probe sonicated for 5 mins (17% duty cycle). 122 mg of BASCA, 50 μL of Ropaque® a synthetic plastic pigment obtained from Dow Chemical) 25 μL of a saturated ethanolic solution of trimesic acid, and 200 μL of 2% aqueous Triton X-100®, an ethoxylated octyl phenol surfactant from Dow chemical solution were added to the mixture and resulting suspension was probe-sonicated for additional 5 min (17% duty cycle).

### Coating of the Substrate

The pre-dyed semiconductor prepared in the previous step was coated onto a fluorine-doped tin oxide (FTO, 8-10 ohms/sq) treated glass substrate using a glass rod drawdown method with 50 micron tape thickness rails and processed in a convection oven at 100° C. for 15 minutes to give a first substrate. The coating coverage is targeted for about 8 to about 12 microns when dried.

### Preparation of the Solar Cell

Another piece of 2 in×2 in FTO treated glass was washed with ethanol and was then ‘painted’ with Platisol® (obtained from Solaronix, Switzerland), dried at room temperature and then baked at 450° C. for 30 minutes. 2 small holes (˜2 mm) were drilled into this piece of glass on the opposite side of the semiconductor and this piece of glass was then heat laminated to the first substrate using a piece of adhesive film (Meltonix®, obtained from Solaronix, Switzerland) cut into the shape of a rectangle and used as a ‘well’ to hold the electrolyte. Lamination was done using clamps and holding the pieces of glass together for 30 minutes @ 150° C.

After assembly the cell was filled with electrolyte (Iodolyte®, obtained from Solarorinx) through one of the filling holes drilled earlier. Both holes were then sealed with the thermal adhesive film.

The resulting cell was placed in a solar simulator and illuminated with 1 Kw/m² intensity and the efficiency of the thus obtained solar cell was determined. The efficiency was 4.95%.

### Example 7

### Cell Made with Polymeric Substrates

A sheet of ITO on Mylar®, polyethylene terephthalate, LR-15® from Solutia Corp, (15 ohms/square) was first treated with a ‘hand held’ corona treating unit and coated with the pre-dyed semiconductor with nanotitania from Example 6 using the procedure described above. The coated semiconductor on the polymeric substrate was dried for 10-30 min at room temperature, and then for 30 min at 100° C.

The cell was constructed using 20 mL of iodide/triiodide/propylene carbonate electrolyte and using as a spacer a piece of Teklon, 20 microns thick microporous polymer film from Entek Membranes Co., with a 1 cm² window cut into it. For a cathode, a piece of LR-15® was used onto which a polyaniline (Panipol®, from Panipol Oy Ltd)/clay (Laponite® EP from Rockwood Clay Additives GmbH) composite was coated. Aluminum foil was used as a reflective layer on the bottom and external to the cell.

The resulting cell was placed in a solar simulator and illuminated with 1 Kw/m² intensity and the efficiency of the thus obtained solar cell was determined. The efficiency was 3.93%.

### Example 8

### Preparation of Pre-Dyed Semiconductor Using Organic Solvent

Into a 50 ml beaker was added 2 grams of P25 Titanium Dioxide; 80 ml of isopropanol, and 50 mg of BASCA dye. This mixture was probe sonicated for 5 minutes in order to create a dispersion. The dispersion was then put on a hot plate and then heated to 70 C in order to evaporate the isopropanol. 78 grams of isopropanol were evaporated and the resulting concentrated dispersion was very pasty. To this mixture was then added 11.4 grams of water and this was then probe sonicated for 5 minutes in order to create a pre-dyed semiconductor dispersion.

This dispersion was coated onto a piece of FTO glass using a glass rod and 2 pieces of 50 micron thick tape as coating rails. After drying at room temperature the cell was baked at 100 C for 20 minutes. It should be noted that isopropanol dispersion above could be coated as is and does not necessarily need to be isolated and redispersed in a water solvent.

Another piece of 2 in×2 in FTO treated glass was washed with ethanol and was then ‘painted’ with Platisol® (obtained from Solaronix, Switzerland), dried at room temperature and then baked at 450° C. for 30 minutes. 2 small holes (˜2 mm) were drilled into this piece of glass on the opposite side of the semiconductor and this piece of glass was then heat laminated to the first substrate using a piece of adhesive film (Meltonix®, obtained from Solaronix, Switzerland) cut into the shape of a rectangle and used as a ‘well’ to hold the electrolyte. Lamination was done using clamps and holding the pieces of glass together for 30 minutes @ 150° C.

After assembly the cell was filled with electrolyte (Iodolyte®, obtained from Solarorinx) through one of the filling holes drilled earlier. Both holes were then sealed with the thermal adhesive film.

The resulting cell was placed in a solar simulator and illuminated with 1 Kw/m² intensity and the efficiency of the thus obtained solar cell was determined.

The efficiency obtained was 2.1%

### Comparative Example

### Conventional Method for Preparing Dyed Semiconductor

To a 2″×2″ piece of FTO coated glass are placed two strips of 2 mil thick tape separated by 1 cm. 75 microliters of a semiconductor dispersion (Solaronix Ti-Nanoxide D) is applied between the tapes and using a glass pipette, the slurry is “draw down” so that it covers the entire 1 cm×5 cm area. The coating dries at room temperature for 20 min followed by 30 min at 75 C in an oven. The tapes are removed and the coating is sintered at 450 C for 30 minutes. After cooling to room temperature the excess TiO2 is scraped off leaving a 1 cm×1 cm square of TiO2

### Conventional Dyeing of the Semiconductor

20 mg of N3 (Solaronix Ruthenizer) is dissolved into 100 mL of ethanol. The glass coated with TiO2 is placed in a petri dish and the N3 solution is poured into the dish, enough to cover the entire slide, especially the semiconductor portion. The petri dish is sealed and the slides are soaked in the dye solution overnight (usually >16 hours). The slides are then removed, rinsed with ethanol and dried at room temperature.

### Conventional Dye Sensitized Solar Cell

Another piece of 2 in×2 in FTO treated glass was washed with ethanol and was then ‘painted’ with Platisol® (obtained from Solaronix, Switzerland), dried at room temperature and then baked at 450° C. for 30 minutes. 2 small holes (˜2 mm) were drilled into this piece of glass on the opposite side of the semiconductor and this piece of glass was then heat laminated to the first substrate using a piece of adhesive film (Meltonix®, obtained from Solaronix, Switzerland) cut into the shape of a rectangle and used as a ‘well’ to hold the electrolyte. Lamination was done using clamps and holding the pieces of glass together for 30 minutes @ 150° C.

The efficiencies of conventional cells are 5.5-6.0%.

The present invention has been described in connection with various embodiments. Notwithstanding the foregoing, it should be understood that modifications, alterations, and additions can be made to the invention without departing from the scope of the invention as defined by the appended claims.

We claim:

1. A method for forming a solar cell comprising the steps of:
a. providing a substrate comprising a first conductor;
b. applying a composition comprising a sensitizing colorant and semiconductor particles; and
c. processing the substrate containing the applied composition at a temperature which retains the sensitizing properties of the colorant.

2. The method of claim 1, wherein the composition further comprises a solvent, wherein the solvent is water or an organic solvent.

3. The method of claim 2, wherein the temperature is below about 350° C.

4. The method of claim 3, wherein the substrate is glass, silicon or a polymeric film.

5. The method of claim 2, wherein the semiconductor particles are comprised of microparticles ranging in size from about 0.1 to about 2 microns and optionally may also comprise nanoparticles ranging in size from 1-100 nanometers.

6. The method of claim 5, wherein the temperature is below about 350° C.

7. The method of claim 6, wherein the substrate is glass, silicon or a polymeric film.

8. The method of claim 3, wherein the composition comprises more than one sensitizing colorant chosen to absorb at different wavelengths of the electromagnetic spectrum, or more than one semiconductor particle type, or both.

9. The method of claim 8, wherein the substrate is glass, silicon or a polymeric film.

10. The method of claim 9, further comprising the steps of:
a. applying an electrolyte layer, and
b. applying a second conductor.

11. Solar cells prepared by the method comprising the steps of:
a. providing a substrate comprising a first conductor;
b. applying a composition comprising a sensitizing colorant and semiconductor particles; and
c. processing the substrate containing the applied composition at a temperature which retains the sensitizing properties of the colorant.

12. The solar cells of claim 11, wherein the composition further comprises a solvent, wherein the solvent is water or an organic solvent.

13. The solar cells of claim 12, wherein the temperature is below about 350° C.

14. The solar cells of claim 13, wherein the substrate is glass, silicon or a polymeric film.

15. The solar cells of claim 12, wherein the semiconductor particles are comprised of microparticles ranging in size from about 0.1 to about 2 microns and optionally may also comprise nanoparticles ranging in size from 1-100 nanometers.

16. The solar cells of claim 15, wherein the temperature is below about 350° C.

17. The solar cells of claim 16, wherein the substrate is glass, silicon or a polymeric film.

18. The solar cells of claim 13, wherein the composition comprises more than one sensitizing colorant chosen to absorb at different wavelengths of the electromagnetic spectrum, or more than one semiconductor particle type, or both.

19. The solar cells of claim 18, wherein the substrate is glass, silicon or a polymeric film.

20. The solar cells of claim 19, further comprising the steps of:
a. applying an electrolyte layer, and
b. applying a second conductor.
